(19) United States
(12) Patent Application Publication
(10) Pub. No.: US 2022/0085063 A1
(43) Pub. Date: Mar. 17, 2022

(54) SEMICONDUCTOR MEMORY DEVICE

(71) Applicant: Kioxia Corporation, Tokyo (JP)

(72) Inventor: Muneyuki TSUDA, Ichinomiya (JP)

(73) Assignee: Kioxia Corporation, Tokyo (JP)

(21) Appl. No.: 17/201,094

(22) Filed: Mar. 15, 2021

(30) Foreign Application Priority Data
Sep. 11, 2020 (JP) 2020-152899

(51) Int. Cl. H01L 27/11582; H01L 23/522; H01L 27/11556

(52) U.S. Cl. CPC H01L 27/11582; H01L 27/11556; H01L 23/5226

(57) ABSTRACT

A semiconductor memory device includes: a plurality of conductive layers; a plurality of insulating layers; a semiconductor layer; and a plurality of electric charge accumulating layers. A conductive layer of the plurality of conductive layers has a first width at a first position where a surface opposed to the semiconductor layer is disposed and has a second width at a second position farther from an electric charge accumulating layer of the plurality of electric charge accumulating layers than the first position. The first width is smaller than the second width, a third width as a maximum width in the electric charge accumulating layer is equal to the first width or smaller than the first width, and the surface at the first position of the conductive layer has no portion that approaches the electric charge accumulating layer from a center to both ends.

### CROSS-REFERENCE TO RELATED APPLICATIONS

This application is based upon and claims the benefit of Japanese Patent Application No. 2020-152899, filed on Sep. 11, 2020, the entire contents of which are incorporated herein by reference.

### BACKGROUND

### Field

Embodiments described herein relate to a semiconductor memory device.

### Description of the Related Art

There has been known a semiconductor memory device that includes a substrate, a plurality of conductive layers disposed in a first direction intersecting with a surface of the substrate and extending in a second direction intersecting with the first direction, a semiconductor layer extending in the first direction and opposed to the plurality of conductive layers, and a gate insulating layer disposed between the plurality of conductive layers and the semiconductor layer.

### BRIEF DESCRIPTION OF THE DRAWINGS

FIG. 1 is a schematic block diagram illustrating a configuration of a semiconductor memory device according to a first embodiment;

FIG. 2 is a schematic block diagram illustrating an exemplary configuration of the semiconductor memory device according to the first embodiment;

FIG. 3 is a schematic circuit diagram illustrating an exemplary configuration of the semiconductor memory device according to the first embodiment;

FIG. 4 is a schematic plan view illustrating an exemplary configuration of the semiconductor memory device according to the first embodiment;

FIG. 5 is a schematic perspective view of a portion indicated by A in FIG. 4;

FIG. 6 is a schematic cross-sectional view of a portion indicated by B in FIG. 5;

FIG. 7 is a schematic cross-sectional view illustrating a manufacturing method of the semiconductor memory device according to the first embodiment;

FIG. 8 is a schematic cross-sectional view illustrating the manufacturing method of the semiconductor memory device according to the first embodiment;

FIG. 9 is a schematic cross-sectional view illustrating the manufacturing method of the semiconductor memory device according to the first embodiment;

FIG. 10 is a schematic cross-sectional view illustrating the manufacturing method of the semiconductor memory device according to the first embodiment;

FIG. 11 is a schematic cross-sectional view illustrating the manufacturing method of the semiconductor memory device according to the first embodiment;

FIG. 12 is a schematic cross-sectional view illustrating the manufacturing method of the semiconductor memory device according to the first embodiment;

FIG. 13 is a schematic cross-sectional view illustrating the manufacturing method of the semiconductor memory device according to the first embodiment;

FIG. 14 is a schematic cross-sectional view illustrating the manufacturing method of the semiconductor memory device according to the first embodiment;

FIG. 15A is a schematic cross-sectional view illustrating a configuration of a semiconductor memory device according to a comparative example;

FIG. 15B is a schematic cross-sectional view illustrating a configuration of a semiconductor memory device according to a comparative example;

FIG. 16A is a schematic cross-sectional view illustrating a configuration according to a modification of the semiconductor memory device according to the first embodiment;

FIG. 16B is a schematic cross-sectional view illustrating a configuration according to a modification of the semiconductor memory device according to the first embodiment;

FIG. 17 is a schematic cross-sectional view illustrating a configuration of a semiconductor memory device according to a second embodiment;

FIG. 18 is a schematic cross-sectional view illustrating a manufacturing method of the semiconductor memory device according to the second embodiment;

FIG. 19 is a schematic cross-sectional view illustrating the manufacturing method of the semiconductor memory device according to the second embodiment;

FIG. 20 is a schematic cross-sectional view illustrating the manufacturing method of the semiconductor memory device according to the second embodiment;

FIG. 21 is a schematic cross-sectional view illustrating the manufacturing method of the semiconductor memory device according to the second embodiment;

FIG. 22 is a schematic cross-sectional view illustrating the manufacturing method of the semiconductor memory device according to the second embodiment;

FIG. 23 is a schematic cross-sectional view illustrating the manufacturing method of the semiconductor memory device according to the second embodiment;

FIG. 24 is a schematic cross-sectional view illustrating the manufacturing method of the semiconductor memory device according to the second embodiment; and

FIG. 25 is a schematic cross-sectional view illustrating the manufacturing method of the semiconductor memory device according to the second embodiment.

### DETAILED DESCRIPTION

A semiconductor memory device according to one embodiment includes: a plurality of conductive layers arranged in a first direction; a plurality of insulating layers each disposed between the plurality of conductive layers; a semiconductor layer that extends in the first direction, the semiconductor layer being opposed to the plurality of conductive layers and the plurality of insulating layers in a second direction intersecting with the first direction; and a plurality of electric charge accumulating layers opposed to the respective plurality of conductive layers and disposed between the plurality of conductive layers and the semiconductor layer. A conductive layer of the plurality of conductive layers has a first width in the first direction at a first position, the first position is where a surface opposed to the semiconductor layer in the second direction of the conductive layer is disposed, the conductive layer has a second width in the first direction at a second position, the second position is farther from an electric charge accumulating layer of the plurality of electric charge accumulating layers in the second direction than the first position, the first width is smaller than the second width, a third width as a maximum width in the first direction in the electric charge accumulating layer is equal to the first width or smaller than the first width, and the surface opposed to the semiconductor layer at the first position of the conductive layer has no portion that approaches the electric charge accumulating layer when the surface is traced from a center of the surface to both ends of the surface in the first direction.

Next, the semiconductor memory devices according to embodiments are described in detail with reference to the drawings. The following embodiments are only examples, and not described for the purpose of limiting the present invention.

The following drawings are schematic, and for convenience of description, a part of a configuration and the like is sometimes omitted. Parts common in a plurality of embodiments are attached by same reference numerals and their descriptions may be omitted.

In this specification, when referring to “semiconductor memory device,” it may mean a memory die and may mean a memory system including a control die, such as a memory chip, a memory card, and an SSD. Further, it may mean a configuration including a host computer such as a smartphone, a tablet terminal, and a personal computer.

In this specification, when referring to that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when referring to that a circuit or the like “electrically conducts” two wirings or the like, it may mean, for example, that this circuit or the like includes a transistor or the like, this transistor or the like is disposed on a current path between the two wirings, and this transistor or the like is turned ON.

In this specification, a direction parallel to an upper surface of a substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined surface may be referred to as a first direction, a direction along this predetermined surface and intersecting with the first direction may be referred to as a second direction, and a direction intersecting with this predetermined surface may be referred to as a third direction. These first direction, second direction, and third direction may correspond to any of the X-direction, the Y-direction, and the Z-direction and need not to correspond to these directions.

In this specification, expressions such as “above” and “below” are based on the substrate. For example, a direction away from the substrate along the Z-direction is referred to as above and a direction approaching the substrate along the Z-direction is referred to as below. A lower surface and a lower end of a certain configuration mean a surface and an end portion on the substrate side of this configuration. An upper surface and an upper end of a certain configuration mean a surface and an end portion on a side opposite to the substrate of this configuration. A surface intersecting with the X-direction or the Y-direction is referred to as a side surface and the like.

In this specification, when referring to a “width” or a “thickness” in a predetermined direction of a configuration, a member, or the like, this may mean a width or a thickness in a cross-sectional surface or the like observed with a Scanning electron microscopy (SEM), a Transmission electron microscopy (TEM), or the like.

### First Embodiment [Memory System 10]

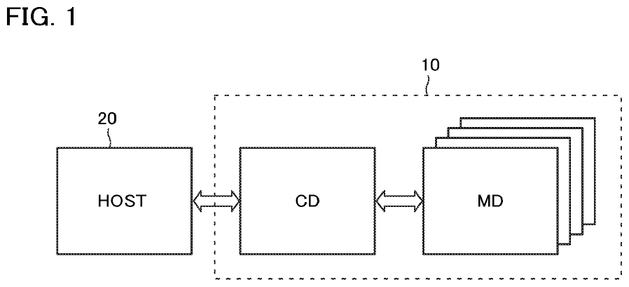

FIG. 1 is a schematic block diagram illustrating an exemplary configuration of a semiconductor memory device according to the first embodiment.

The memory system 10, for example, reads, writes, and erases user data in response to a signal transmitted from a host computer 20. The memory system 10 is, for example, any system that can store the user data including a memory chip, a memory card, and an SSD. The memory system 10 includes a plurality of memory dies MD that store the user data and a control die CD connected to the plurality of memory dies MD and the host computer 20. The control die CD includes, for example, a processor, a RAM, and the like, and performs conversion between a logical address and a physical address, bit error detection/correction, a garbage collection (compaction), a wear leveling, and the like.

[Configuration of Memory Die MD]

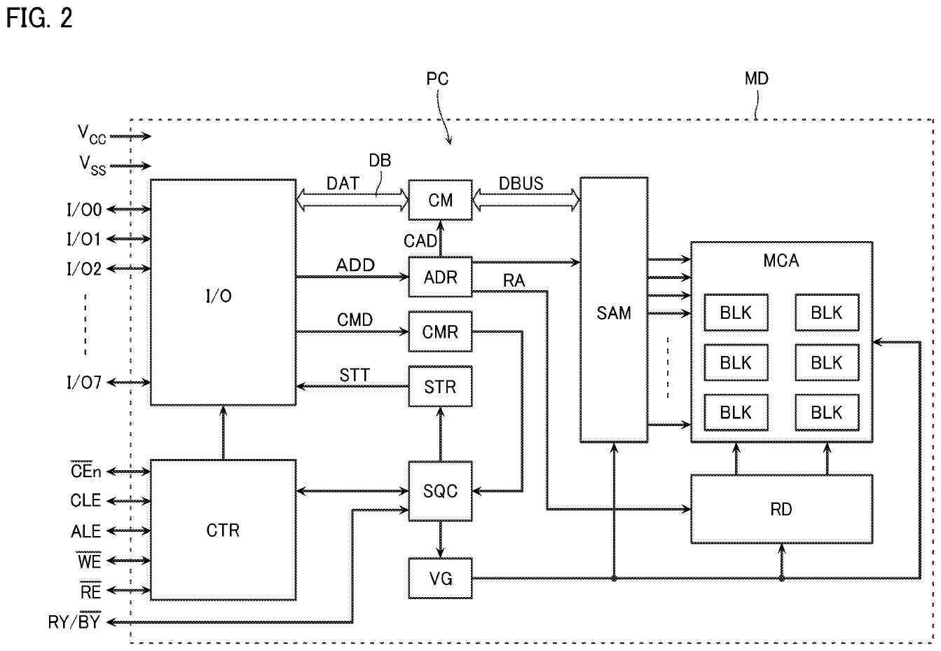

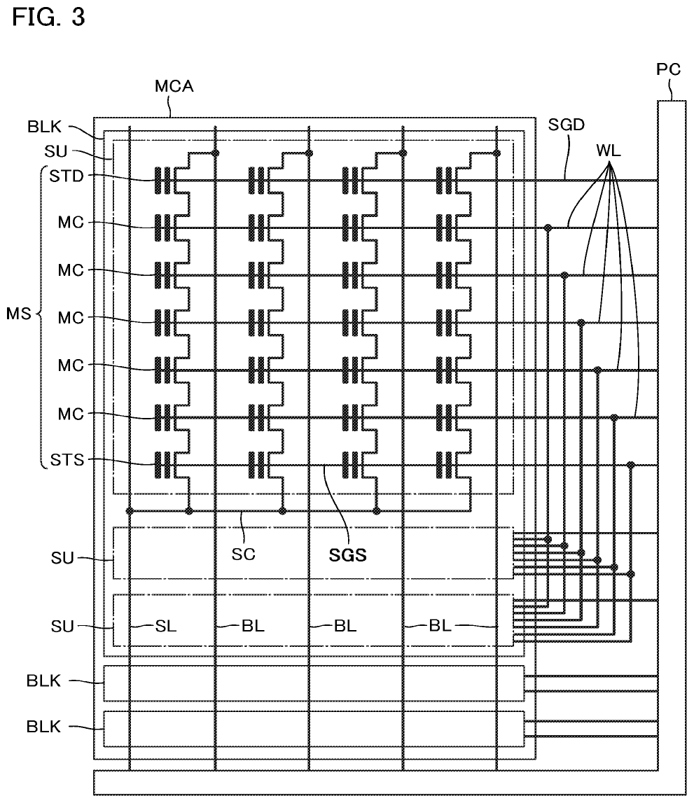

FIG. 2 is a schematic block diagram illustrating an exemplary configuration of the semiconductor memory device according to the embodiment and FIG. 3 is a schematic circuit diagram illustrating the same.

As illustrated in FIG. 2, the memory die MD includes a memory cell array MCA that stores data and a peripheral circuit PC connected to the memory cell array MCA. The peripheral circuit PC includes a voltage generation circuit VG, a row decoder RD, a sense amplifier module SAM, and a sequencer SQC. The peripheral circuit PC includes a cache memory CM, an address register ADR, a command register CMR, and a status register STR. The peripheral circuit PC includes an input/output control circuit I/O and a logic circuit CTR.

The voltage generation circuit VG includes, for example, a step up circuit such as a charge pump circuit, a step down circuit such as a regulator, and a plurality of voltage supply lines (not illustrated), which are connected to power supply terminal VCC and VSS. The voltage generation circuit VG generates a plurality of patterns of operating voltages applied to a bit line BL, a source line SL, a word line WL, and a select gate line (SGD, SGS) in a read operation, a write operation, and an erase operation on the memory cell array MCA, in accordance with an internal control signal from a sequencer SQC to simultaneously output the operating voltages from the plurality of voltage supply lines.

The row decoder RD includes, for example, a decode circuit and a switch circuit. The decode circuit decodes a row address RA held in the address register ADR. The switch circuit electrically conducts the word line WL and the select gate line (SGD, SGS) corresponding to the row address RA with corresponding voltage supply lines in accordance with an output signal of the decode circuit.

The sense amplifier module SAM includes a plurality of sense amplifier circuits corresponding to the plurality of bit lines BL, a plurality of voltage adjustment circuits, and a plurality of data latches. The sense amplifier circuit causes the data latch to latch data of “H” or “L” indicative of ON/OFF of the memory cell MC according to a current or a voltage of the bit line BL. The voltage adjustment circuit electrically conducts the bit line BL with the corresponding voltage supply line according to the data latched by the data latch.

The sense amplifier module SAM includes a decode circuit and a switch circuit (not illustrated). The decode circuit decodes a column address CAD held in the address register ADR.

The switch circuit electrically conducts the data latch corresponding to the column address CAD with the bus DB, via a data bus DBUS and a cache memory CM, in accordance with an output signal of the decode circuit.

The sequencer SQC sequentially decodes command data CMD held in the command register CMR and outputs an internal control signal to the row decoder RD, the sense amplifier module SAM, and the voltage generation circuit VG. The sequencer SQC outputs status data STT indicating its own state to the status register STR, as necessary.

The input/output control circuit I/O includes data input/output terminals I/O0 to I/O7, shift registers connected to these data input/output terminals I/O0 to I/O7, and a buffer memory connected to this shift register.

The buffer memory outputs data to the data latch in the sense amplifier module SAM, the address register ADR, or the command register CMR, in accordance with the internal control signal from the logic circuit CTR. The buffer memory inputs data from the data latch or the status register STR, in accordance with the internal control signal from the logic circuit CTR. The buffer memory may be achieved by some of the shift registers and may be achieved by a configuration of an SRAM or the like.

The logic circuit CTR receives an external control signal from a control die CD via external control terminals /CEn, CLE, ALE, /WE, and /RE to output the internal control signal to the input/output control circuit I/O in accordance with this.

As illustrated in FIG. 3, the memory cell array MCA includes a plurality of memory blocks BLK. The plurality of memory blocks BLK each include a plurality of string units SU. The plurality of string units SU each include a plurality of memory strings MS. The plurality of memory strings MS have one ends each connected to the peripheral circuit PC via a bit line BL. The plurality of memory strings MS have other ends each connected to the peripheral circuit PC via a lower wiring SC and a common source line SL.

The memory string MS includes a drain-side select transistor STD, a plurality of memory cells MC (memory transistors), a source-side select transistor STS, which are connected in series between the bit line BL and the source line SL. Hereinafter, the drain-side select transistor STD and the source-side select transistor STS may be simply referred to as select transistors (STD, STS).

The memory cell MC is a field-effect type transistor including a semiconductor layer that functions as a channel region, a gate insulating layer including an electric charge accumulating layer, and a gate electrode. The memory cell MC has a threshold voltage that changes according to an electric charge amount in the electric charge accumulating layer. The memory cell MC stores one bit or a plurality of bits of data. Word lines WL are connected to respective gate electrodes of the plurality of memory cells MC corresponding to one memory string MS. These respective word lines WL are connected to all of the memory strings MS in one memory block BLK in common.

The select transistor (STD, STS) is a field-effect type transistor including a semiconductor layer that functions as a channel region, a gate insulating film, and a gate electrode. The select gate lines (SGD, SGS) are connected to the respective gate electrodes of the select transistors (STD, STS). The drain side select gate line SGD is disposed corresponding to the string unit SU and connected to all of the memory strings MS in one string unit SU in common. The source side select gate line SGS is connected to all of the memory strings MS in the plurality of string units SU in one memory block BLK in common.

[Structure of Memory Die MD]

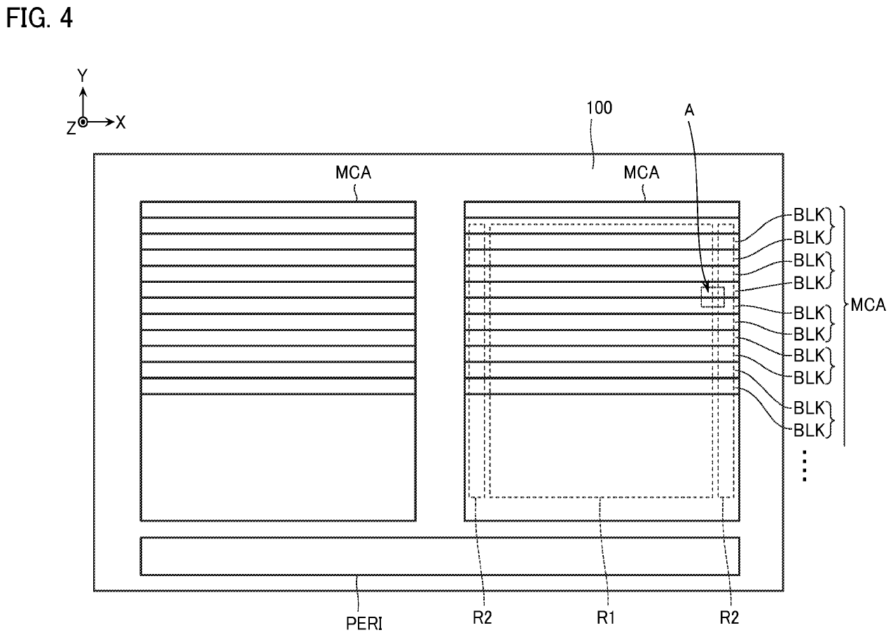

FIG. 4 is a schematic plan view illustrating an exemplary configuration of the semiconductor memory device according to the embodiment, and illustrates a planar structure of the memory die MD.

As illustrated in FIG. 4, on a substrate 100, the plurality of memory cell arrays MCA and a region PERI are disposed. In the example illustrated in the drawing, two memory cell arrays MCA are arranged in the X-direction and the PERI is disposed at one end in the Y-direction on the substrate 100.

The memory cell array MCA includes a plurality of memory blocks BLK arranged in the Y-direction. The memory cell array MCA includes a region R1 where the memory cell MC is disposed and a region R2 where contacts CC and the like are disposed in a stair pattern. The region PERI includes, for example, a part of the peripheral circuit PC, pad electrodes, and the like.

[Memory Cell Array MCA]

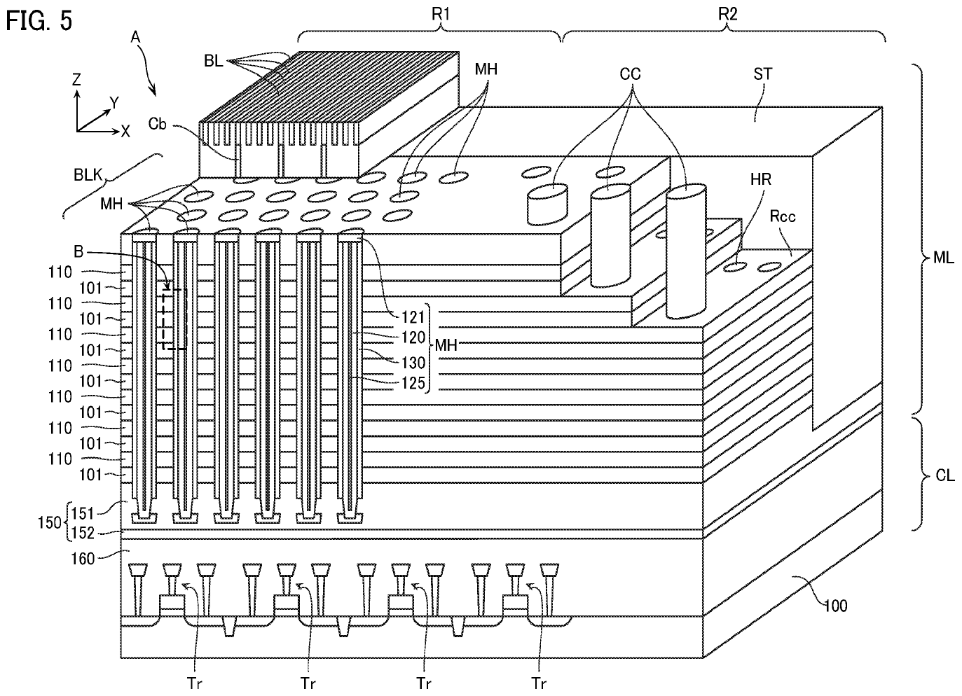

FIG. 5 is a schematic perspective view of the portion indicated by A in FIG. 4.

As illustrated in FIG. 5, the memory cell array MCA includes a memory layer ML and a circuit layer CL disposed below the memory layer ML.

[Memory Layer ML]

In the memory layer ML, for example, as illustrated FIG. 5, an inter-block insulating layer ST that extends in the X-direction and the Z-direction is disposed between the two memory blocks BLK mutually adjacent in the Y-direction. Note that the inter-block insulating layer ST may be disposed only on both sides between two memory blocks BLK in the Y-direction. An inter-block conductive layer (not illustrated) extending in the X-direction and the Z-direction may be formed in a center portion of the inter-block insulating layer ST in the Y-direction. The inter-block conductive layer may be electrically connected to a lower wiring layer 150 and function as a contact relative to the lower wiring layer 150.

As illustrated in FIG. 5, the memory block BLK includes the following: a plurality of memory hole structures MH extending in the Z-direction; a plurality of conductive layers 110, arranged in the Z-direction, covering an outer peripheral surface of the plurality of memory hole structures MH in the XY cross-sectional surface; a plurality of insulating layers 101 arranged between the plurality of conductive layers 110; the plurality of bit lines BL connected to an upper end of the memory hole structure MH; and the lower wiring layer 150 connected to a lower end of the memory hole structure MH.

The plurality of memory hole structures MH are arranged in a predetermined pattern in the X-direction and the Y-direction. The memory hole structure MH includes a semiconductor layer 120 extending in the Z-direction, a gate insulating layer 130 disposed between the semiconductor layer 120 and the conductive layers 110, a semiconductor layer 121 connected to the upper end of the semiconductor layer 120, and an insulating layer 125 disposed in the center portion of the memory hole structure MH.

The semiconductor layer 120 functions, for example, as a channel region of the plurality of memory cells MC, the drain-side select transistor STD, and the source-side select transistor STS included in one memory string MS (FIG. 3). The semiconductor layer 120 has a substantially cylindrical shape integrally formed from the lower end to the upper end. The semiconductor layer 120 has a center portion into which the insulating layer 125 such as silicon oxide (SiO₂) is filled. The semiconductor layer 120 includes, for example, a semiconductor such as non-doped polycrystalline silicon (Si).

The gate insulating layer 130 extends in the Z-direction along the outer peripheral surface of the semiconductor layer 120 and has a substantially cylindrical shape integrally formed from the lower end to the upper end.

The semiconductor layer 121 includes, for example, a semiconductor such as polycrystalline silicon (Si) where N type impurities such as phosphorus (P) are doped.

The plurality of conductive layers 110 are conductive films having a substantially plate shape and arranged in the Z-direction via the insulating layer 101. Each of the plurality of conductive layers 110 extend in the X-direction and the Y-direction. Among the plurality of conductive layers 110, some of conductive layers 110 arranged in the center portion in the Z-direction function as the word lines WL (FIG. 3) and gate electrodes of the plurality of memory cells MC (FIG. 3) connected to the word lines WL.

Among the plurality of conductive layers 110, some of conductive layers 110 arranged on an upper side in the Z-direction function as the drain side select gate line SGD (FIG. 3) and the gate electrodes of the plurality of drain-side select transistors STD (FIG. 3) connected to this drain side select gate line SGD.

Among the plurality of conductive layers 110, some of conductive layers 110 arranged on a lower side in the Z-direction function as the source side select gate line SGS (FIG. 3) and the gate electrodes of the plurality of source-side select transistors STS (FIG. 3) connected thereto.

The insulating layers 101 are each disposed between the plurality of conductive layers 110 arranged in the Z-direction. The insulating layers 101 are, for example, an insulating film such as silicon oxide (SiO₂).

The plurality of bit lines BL are arranged in the X-direction and extend in the Y-direction. The bit line BL is connected to the semiconductor layer 120 via a contact Cb or the like and the semiconductor layer 121.

The lower wiring layer 150 includes, for example, as illustrated in FIG. 5, a semiconductor layer 151 connected to the semiconductor layer 120 and a conductive layer 152 disposed on the lower surface of the semiconductor layer 151. The lower wiring layer 150 functions as the lower wiring SC (FIG. 3).

The conductive layer 152 is formed on the substrate 100 via an insulating layer 160. The conductive layer 152 includes, for example, a conductive film of a metal such as tungsten (W), polycrystalline silicon (Si) where N type impurities such as phosphorus(P) are doped, or silicide. The semiconductor layer 151 includes, for example, polycrystalline silicon (Si) where N type impurities such as phosphorus(P) are doped. The insulating layer 160 is, for example, an insulating film such as silicon oxide (SiO₂).

[Circuit Layer CL]

The circuit layer CL includes, for example, as illustrated in FIG. 5, the substrate 100, a plurality of transistors Tr constituting the peripheral circuit PC, a plurality of wirings and contacts connected to the plurality of transistors Tr.

The substrate 100 is a semiconductor substrate made of, for example, single-crystal silicon (Si). The substrate 100 includes a double well structure that has, for example, an N-type impurity layer of phosphorus (P) and the like and further has a P-type impurity layer such as boron (B) in this N-type impurity layer, on a surface of a semiconductor substrate.

[Structure of Memory Cell MC]

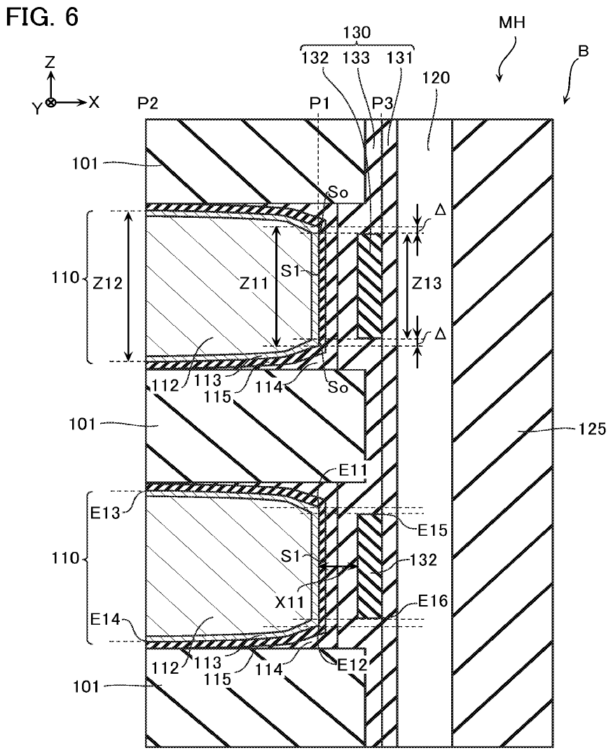

FIG. 6 is a schematic cross-sectional view of a portion indicated by B in FIG. 5 and illustrates details of a structure at a position where the conductive layers 110 and the gate insulating layer 130 are mutually opposed.

While FIG. 6 indicates the configuration on the cross-sectional surface (XZ cross-sectional surface) along the X-direction and Z-direction, of a part of the memory hole structure MH, the memory hole structure MH includes a similar configuration even on a cross-sectional surface along the extending direction of the conductive layer 110 other than the X-direction and the Z-direction. In the following, while the configuration of the embodiment is continuously described with, for example, the X-direction as the extending direction of the conductive layer 110, cross-sectional configurations in other directions along the extending direction of the conductive layer 110 are also similarly understood.

As illustrated in FIG. 6, the gate insulating layer 130 includes a tunnel insulating layer 131, an electric charge accumulating layer 132, and a block insulating layer 133 stacked between the semiconductor layer 120 and the conductive layer 110. While the tunnel insulating layer 131 and the block insulating layer 133 are integrally and continuously disposed in the Z-direction, the electric charge accumulating layer 132 is separated in the Z-direction. The plurality of electric charge accumulating layers 132 are each disposed at the position opposed to the plurality of conductive layers 110 in the X-direction. The block insulating layer 133 is formed so as to cover surfaces on the conductive layer 110 side and both end surfaces in the Z-direction of the plurality of electric charge accumulating layers 132 in the X-direction and the Z-direction.

The tunnel insulating layer 131 and the block insulating layer 133 are, for example, the insulating layers such as silicon oxide (SiO₂). The electric charge accumulating layer 132 is, for example, a layer such as silicon nitride (SiN) or the like that can accumulate the electric charge. The electric charge accumulating layer 132 may be, for example, a floating gate made of polycrystalline silicon (Si) where the N type impurities such as phosphorus (P) or the P type impurities such as boron (B) are doped, non-doped polycrystalline silicon (Si), or the like.

The conductive layer 110 includes a conductive layer 112 and a barrier metal layer 113. The conductive layer 112 extends in the X-direction. The barrier metal layer 113 covers an upper surface, a lower surface, and a side surface of the conductive layer 112. The conductive layer 112 is, for example, a metal film containing tungsten (W) or molybdenum (Mo). The barrier metal layer 113 is, for example, a metal film such as titanium nitride (TiN). An upper surface, a lower surface, and a side surface of the conductive layer 110 are covered by an insulating layer 115. The insulating layer 115 is, for example, a high dielectric constant film (high-k film) containing aluminum oxide (Al₂O₃) or the like.

A width in the Z-direction of the conductive layer 110 becomes smaller as approaching the electric charge accumulating layer 132 side in the X-direction. That is, the conductive layer 110 is disposed such that the side opposed to the semiconductor layer 120 is what is called a tapered shape.

The conductive layer 110 has a width Z11 in the Z-direction at a first position P1. The first position P1 is where a surface S1 opposed to the semiconductor layer 120 in the X-direction of the conductive layer 110 is disposed. The conductive layer 110 has a width Z12 in the Z-direction at a second position P2. The second position P2 is farther from the electric charge accumulating layer 132 in the X-direction than the first position P1. The width Zil is smaller than the width Z12. A thickness of the conductive layer 110 continuously increases monotonously from the portion of the width Z11 to the portion of the width Z12.

The surface S1 of the conductive layer 110 has no portion that approaches the semiconductor layer 120 when the surface is traced from the center to both ends in the Z-direction. As one example, a distance between the surface S1 of the conductive layer 110 and the semiconductor layer 120 is substantially constant over an entire region in the Z-direction, the entire region is where the surface S1 and the semiconductor layer 120 are mutually opposed and spaced in the X-direction. A separation distance X11 between an opposed surface where the electric charge accumulating layer 132 is opposed to the surface S1 of the conductive layer 110 and the surface S1 is substantially constant over an entire region in the Z-direction.

Note that the surface S1 may be disposed to be slightly separated from the semiconductor layer 120 between the center to both ends in the Z-direction. The surface S1 may be a surface where the conductive layer 110 is closest to and opposed to the semiconductor layer 120 in the X-direction, and the opposed surface where the electric charge accumulating layer 132 is opposed to the surface S1 of the conductive layer 110 may be a surface where the electric charge accumulating layer 132 is closest to and opposed to the conductive layer 110.

The electric charge accumulating layer 132 has a width Z13 as the maximum width in the Z-direction. The width Z13 is equal to the width Z11 of the surface S1 of the conductive layer 110 or smaller than the width Z11.

The surface S1 at the first position P1 of the conductive layer 110 has respective offset portions So on at least one side or both sides of the upper end and the lower end in the Z-direction. The offset portions So are opposed to the semiconductor layer 120 without via the electric charge accumulating layer 132. An offset amount Δ that is a length of the offset portion So in the Z-direction is, for example, equal to or more than 0 and smaller than (Z12-Z13)/2. Note that the offset amounts Δ in the offset portions So at both sides in the Z-direction may be different with one another.

The conductive layer 110 has a first end portion E11 on one side in the Z-direction and a second end portion E12 on the other side in the Z-direction. The first position P1 is where the surface S1 closest to and opposed to the semiconductor layer 120 in the X-direction is disposed. The conductive layer 110 has a third end portion E13 on one side in the Z-direction and a fourth end portion E14 on the other side in the Z-direction at the second position P2. The second position P2 is farther from the electric charge accumulating layer 132 in the X-direction than the first position Pl. The electric charge accumulating layer 132 has a fifth end portion E15 on one side in the Z-direction and a sixth end portion E16 on the other side in the Z-direction at a third position P3. The third position P3 is where the electric charge accumulating layer 132 has the maximum width in the Z-direction. In the Z-direction, the first end portion E11 may be positioned at a position same as the fifth end portion E15 or between the third end portion El3 and the fifth end portion E15. In the Z-direction, the second end portion E12 may be positioned at a position same as the sixth end portion E16 or between the fourth end portion E14 and the sixth end portion E16.

The distance between the first end portion E11 and the fifth end portion E15 in the Z-direction may be equal to or more than zero and smaller than the distance between the third end portion E13 and the fifth end portion E15 in the Z-direction. The distance between the second end portion E12 and the sixth end portion E16 in the Z-direction may be equal to or more than zero and smaller than the distance between the fourth end portion E14 and the sixth end portion E16 in the Z-direction.

In a portion where the width in the Z-direction of the conductive layer 110 monotonously increases over the X-direction, an insulating layer 114 is disposed so as to fill the space between the insulating layer 101 and the insulating layer 115. The insulating layer 114 is further disposed between the insulating layer 115 and the block insulating layer 133.

[Operation]

Next, a write operation, an erase operation, and a read operation of the memory cell MC of the semiconductor memory device thus configured are described.

When the write operation or the erase operation to the memory cell MC is performed in the semiconductor memory device of the embodiment, negative electric charges or positive electric charges are accumulated in the electric charge accumulating layer 132. Accumulation of electric charges to the electric charge accumulating layer 132 is performed by applying a predetermined first voltage between the conductive layer 110 and the semiconductor layer 120 to draw the negative electric charges or positive electric charges from the semiconductor layer 120 into the electric charge accumulating layer 132 via the tunnel insulating layer 131.

When the read operation to the memory cell MC is performed in the semiconductor memory device of the embodiment, a predetermined second voltage for reading is applied between the conductive layer 110 and the semiconductor layer 120 to determine an electric charge amount accumulated in the electric charge accumulating layer 132. Because a threshold voltage where the channel of the semiconductor layer 120 is turned ON varies by the electric charge amount accumulated in the electric charge accumulating layer 132, the accumulated electric charge amount is determined by determining the magnitude of the second voltage where the channel is turned ON.

[Manufacturing Method]

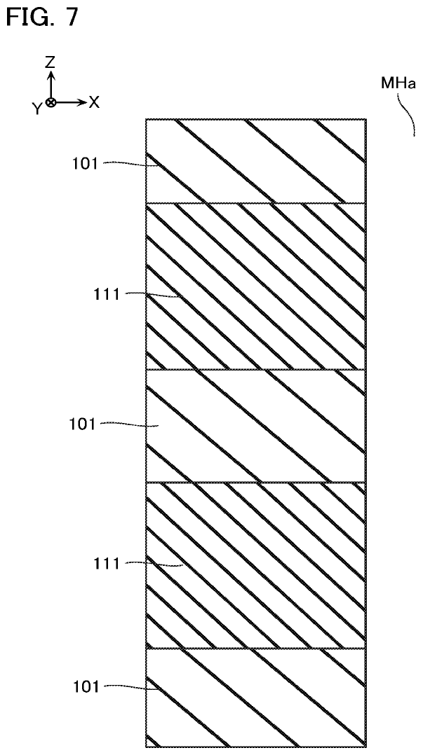

Next, with reference to FIG. 7 to FIG. 14, the manufacturing method of the semiconductor memory device according to the embodiment is described. FIG. 7 to FIG. 14 are partial cross-sectional views describing the manufacturing method of the semiconductor memory device illustrated in FIG. 6.

In the manufacturing method of the semiconductor memory device according to the embodiment, as illustrated in FIG. 5, the insulating layer 160, the conductive layer 152, and the semiconductor layer 151 are formed on the substrate 100. As illustrated in FIG. 7, the plurality of insulating layers 101 and a plurality of sacrifice layers 111 are alternately formed above these. The insulating layer 101 is made of, for example, silicon oxide (SiO₂) or the like. The sacrifice layer 111 is made of, for example, silicon nitride (SiN) or the like. This process is performed, for example, by a method such as Chemical Vapor Deposition (CVD).

The substrate 100 is, for example, a substrate where the transistors Tr of the circuit layer CL as illustrated in FIG. 5, or the like, are formed, or a semiconductor substrate such as Si. The insulating layer 160 is made of, for example, silicon oxide or the like. The conductive layer 152 contains, for example, tungsten silicide (WSi) or the like. The semiconductor layer (lower wiring layer) 151 is, for example, a conductive layer containing polysilicon (Si) where phosphorus (P) is doped or the like.

Next, as illustrated in FIG. 7, an opening MHa for forming the memory cell MC in a stacked body made of the insulating layers 101 and the sacrifice layers 111 is formed. This process is performed, for example, by a method such as Reactive Ion Etching (RIE).

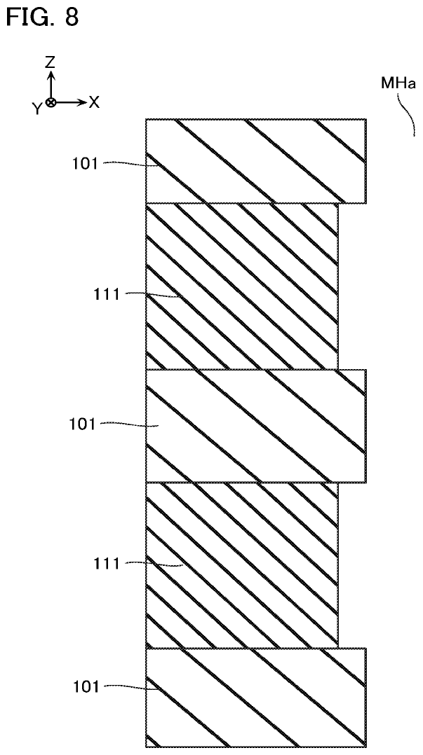

Next, as illustrated in FIG. 8, etching is performed. The etching selectively recesses sidewall portions of the sacrifice layers 111 facing the opening MHa backward in the stacked body made of the insulating layers 101 and the sacrifice layers 111, with respect to the sidewall portions of the insulating layers 101. This process is performed, for example, by a method such as wet etching or dry etching.

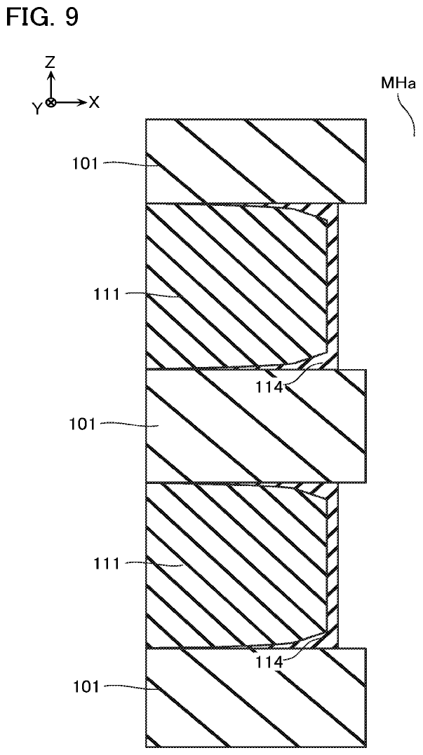

Next, as illustrated in FIG. 9, of the sacrifice layer 111, the sidewall portion recessed backward and exposed undergoes an oxidation treatment. Of the sacrifice layer 111, the oxidation starts from the sidewall portion facing the opening MHa and further partially progresses to a portion where the sacrifice layer 111 and the insulating layers 101 are in contact with one another vertically in the Z-direction. With this oxidation treatment, the insulating layer 114 that covers the sidewall portion of the sacrifice layer 111, and an upper surface and a lower surface adjacent to the sidewall portion of sacrifice layer 111 is formed. The insulating layer 114 is made of, for example, silicon oxide (SiO₂) or the like. This process is performed, for example, by a method such as a thermal oxidation treatment where oxidant is used.

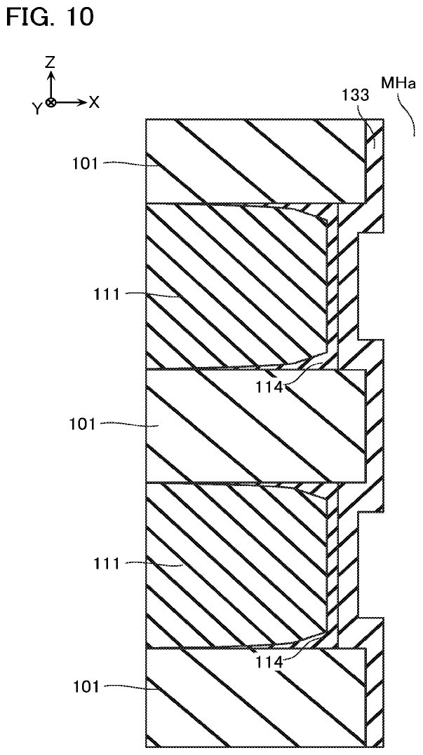

Next, as illustrated in FIG. 10, the block insulating layer 133 is formed with a thickness to an extent that does not fill a difference in level of the sidewall of the opening MHa, on the entire sidewall of the opening MHa. The block insulating layer 133 is made of, for example, silicon oxide (SiO₂) or the like. This process is performed, for example, by a method such as CVD.

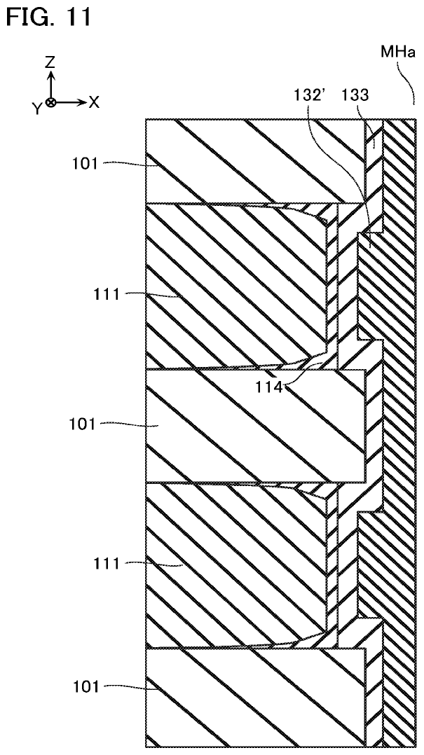

Subsequently, as illustrated in FIG. 11, an electric charge accumulating layer 132′ is formed on the block insulating layer 133 so as to fill the difference in level of the sidewall of the opening MHa. The electric charge accumulating layer 132′ may be a film of, for example, silicon. nitride (SiN) or the like that can accumulate the electric charges. The electric charge accumulating layer 132′ may be a floating gate made of polycrystalline silicon (Si) where the N type impurities such as phosphorus (P) or P type impurities such as boron (B) are doped, non-doped polycrystalline silicon (Si), or the like. This process is performed, for example, by a method such as CVD.

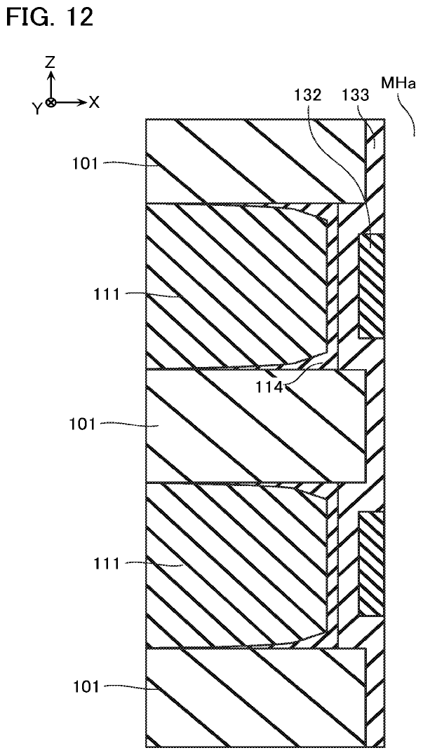

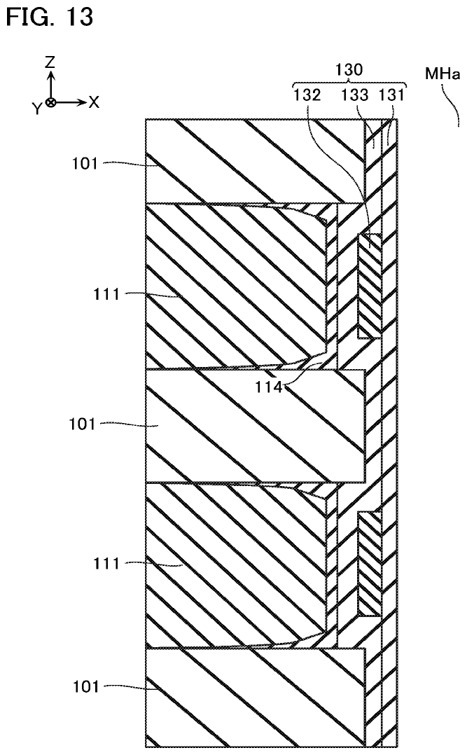

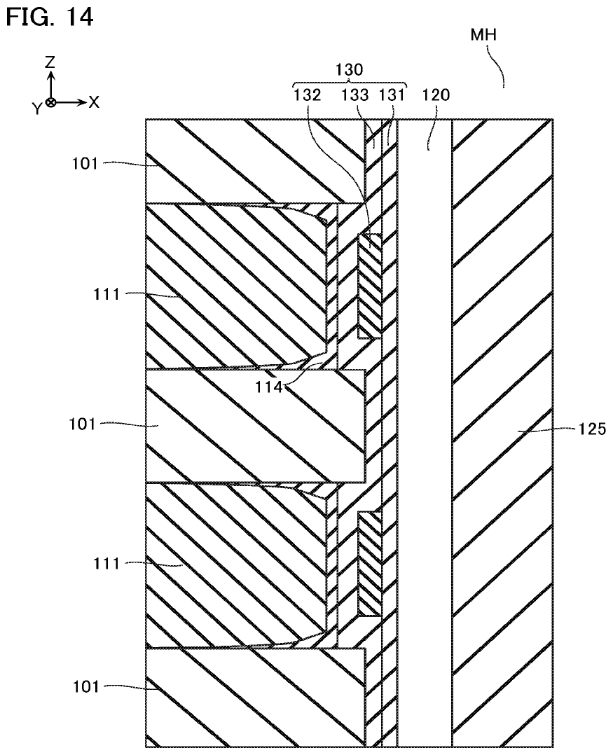

Next, as illustrated in FIG. 12, the recess etching that recesses the electric charge accumulating layer 132′ backward is performed. This separates the electric charge accumulating layer 132′ in the stacking direction of the stacked body of the insulating layers 101 and the sacrifice layers 111. The electric charge accumulating layer 132 in the portion opposed to the center portion in the stacking direction of the sacrifice layer 111 is left. This process is performed, for example, by a method such as the wet etching or the dry etching. Next, as illustrated in FIG. 13, the tunnel insulating layer 131 is formed on the electric charge accumulating layer 132. The tunnel insulating layer 131 is made of, for example, silicon oxide (SiO₂) or the like. This process is performed, for example, by a method such as the thermal oxidation. Next, as illustrated in FIG. 14, the semiconductor layer 120 and the insulating layer 125 are sequentially formed. This forms the substantially columnar shaped memory hole structure MH. This process is performed, for example, by a method such as CVD. In this process, for example, a heat treatment for modifying a crystalline structure of the semiconductor layer 120, a formation processing of the semiconductor layer for a cap covering an upper end portion of the insulating layer 125 after recessing at least the upper end portion of the insulating layer 125 backward, and the like are performed.

Next, the plurality of sacrifice layers 111 are removed via an opening (not illustrated) to form cavities. Subsequently, after the insulating layer 115 has been formed in the cavity formed by removing the sacrifice layer 111, the barrier metal layer 113 and the conductive layer 112 are sequentially formed to form the conductive layer 110. The process to remove the sacrifice layer 111 is performed, for example, by a method such as the wet etching. The formation of the insulating layer 115, the barrier metal layer 113, and the conductive layer 112 is performed, for example, by a method such as CVD. With the processes described above, the configuration described with reference to FIG. 6 is formed.

[Effect]

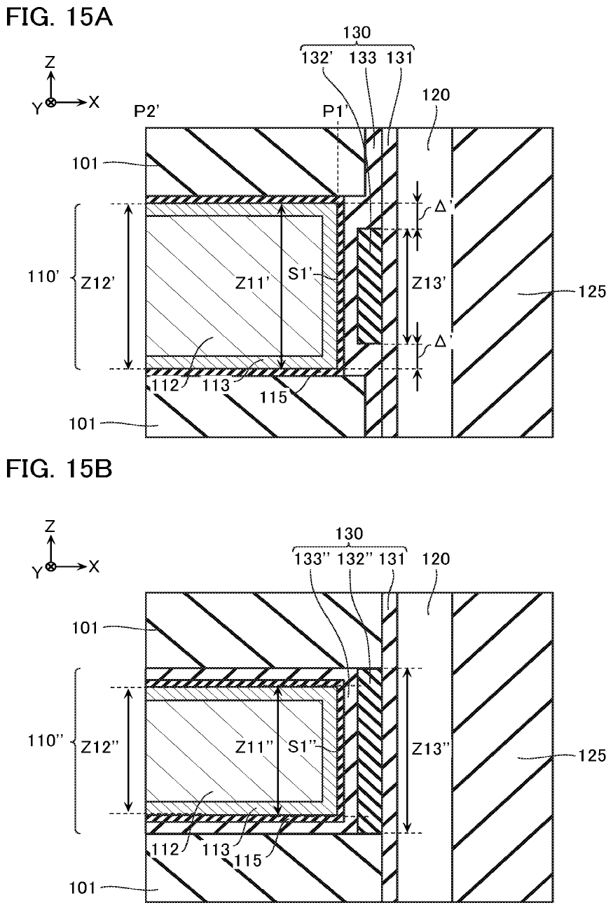

Effect of the embodiment is described with reference to comparative examples illustrated in FIG. 15A and FIG. 15B. FIG. 15A and FIG. 15B are schematic cross-sectional views illustrating semiconductor memory devices according to the comparative examples and illustrate portions that correspond to the cross-sectional structure of the embodiment illustrated in FIG. 6.

FIG. 15A illustrates the comparative example where a width Z11′ in the Z-direction at a first position P1′ and a width Z12′ in the Z-direction at a second position P2′ of a conductive layer 110′ are equal, that is, the conductive layer 110′ does not have a tapered shape. Similarly to the embodiment, when the manufacturing method, which is illustrated in FIG. 8 to FIG. 12, where the electric charge accumulating layer 132′ is formed by performing the recess etching on the sacrifice layer 111 from the opening MHa side is employed, it is necessary to separate the sacrifice layer 111 and the electric charge accumulating layer 132′ by the block insulating layer 133 such that the electric charge accumulating layer 132′ is not etched at a time of replacement of the sacrifice layer 111. Thus, as illustrated in FIG. 15A, a width Z13′ in the Z-direction of the electric charge accumulating layer 132′ becomes smaller than the width Z11′ (=Z12′) of the conductive layer 110′ by a film thickness of the block insulating layer 133. In this case, offset amounts A where both ends in the Z-direction of a surface S1′ opposed to the semiconductor layer 120 of the conductive layer 110′ protrude in the Z-direction out of both ends in the Z-direction of the electric charge accumulating layer 132′ are each equal to (Z12′-Z13′)/2. There is a following problem in this comparative example.

That is, in such structure, in the read operation of the memory cell MC, the electric charge accumulating layer 132′ is not present between portions corresponding to the offset amounts A at both ends in the Z-direction of the conductive layer 110′ and portions of the semiconductor layer 120 opposed to the portions corresponding to the offset amounts A, and thus an electric field generated between the conductive layer 110′ and the semiconductor layer 120 is not shielded by negative electric charges accumulated in the electric charge accumulating layer 132′. In this case, in portions of the semiconductor layer 120 opposed to both end portions in the Z-direction of the conductive layer 110′ where a higher electric field is generated, the channel turns ON at a low voltage unintended in the design and accuracy of the original read operation may be deteriorated. Consequently, in this comparative example, it is unable to achieve satisfactory read characteristics of the memory cell MC. Thus, for example, as the comparative example illustrated in FIG. 15B, it is also considered to form a width Z13″ in the Z-direction of an electric charge accumulating layer 132″ to be equal to or more than a width Z11″ in the Z-direction of the surface S1″ of a conductive layer 110″.

However, in the manufacturing process in this case, after removing the sacrifice layer 111 for forming the conductive layer 110″, a process of selectively forming the electric charge accumulating layer 132″ in a cavity generated by removing the sacrifice layer 111 and, subsequently, forming a block oxide film 133″ is necessary, or it is necessary to generate a stacked structure body of two kinds of sacrifice layers and replace these two kinds of sacrifice layers with the insulating layer 101 and the conductive layer 110, respectively. Both of them have a problem that the manufacturing process is complicated.

When, as the comparative example illustrated in FIG. 15B, the width Z13″ in the Z-direction of the electric charge accumulating layer 132″ is larger than the width Z11″ in the Z-direction of the surface Si″ of the conductive layer 110″, there is a problem that erase characteristics in a region where an erase voltage in the erase operation is high is deteriorated to reduce a window width of write/erase voltage versus threshold characteristics.

In the comparative example illustrated in FIG. 15B, at both end portions in the Z-direction of the electric charge accumulating layer 132″, the amount of the accumulated electric charge is reduced compared to the center portion in the Z-direction, and thus reliability of write/erase operation is deteriorated. Consequently, in this comparative example, while satisfactory read characteristics can be obtained, satisfactory write/erase characteristics cannot be achieved.

Thus, in the embodiment, as illustrated in FIG. 6, the conductive layer 110 and the electric charge accumulating layer 132 are disposed such that the width Z11 in the Z-direction of the conductive layer 110 at the first position P1 on the semiconductor layer 120 side is smaller than the width Z12 at the second position P2 apart from the semiconductor layer 120, and the width Z13 of the electric charge accumulating layer 132 is equal to the width Z11 of the conductive layer 110 or smaller than the width Z11. The offset amount A in the Z-direction with respect to the electric charge accumulating layer 132 at both ends of the surface S1 of the conductive layer 110 is set to be equal to or more than zero and smaller than (Z12-Z13)/2.

In the structure of the embodiment, in the entire region from both end portions in the Z-direction to the center portion in the Z-direction of the electric charge accumulating layer 132, the distance between the surface S1 and the electric charge accumulating layer 132 can be set to be substantially constant and the sufficient electric charge amount can be uniformly accumulated in the electric charge accumulating layer 132. Consequently, in the embodiment, both the satisfactory read characteristics and the satisfactory write/erase characteristics can be achieved. This provides the effect that the reliability of the memory cell MC is improved.

[Modification]

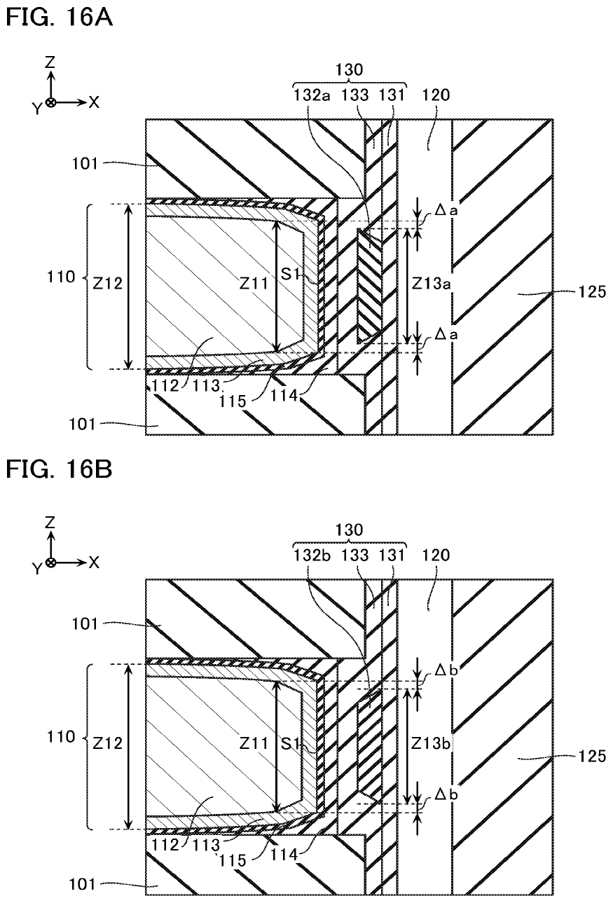

FIG. 6 illustrates the shape where the electric charge accumulating layer 132 has the width Z13 in the Z-direction and the thickness (width in the X-direction) is substantially constant over the Z-direction. On the other hand, the electric charge accumulating layer 132 need not necessarily be disposed in a shape where the thickness is substantially constant over the Z-direction. FIG. 16A and FIG. 16B are schematic cross-sectional views of semiconductor memory devices according to the modifications.

In FIG. 16A, instead of the electric charge accumulating layer 132, an electric charge accumulating layer 132a is disposed. In the electric charge accumulating layer 132a, a surface close to the conductive layer 110 has a width Z13a in the Z-direction and a surface far from the conductive layer 110 has a width in the Z-direction smaller than the width Z13a. In this case, the electric charge accumulating layer 132a is disposed such that the width Z13a is equal to the width Z11 of the conductive layer 110 or smaller than the width Z11 by an offset amount Δa at an upper end and a lower end in the Z-direction.

In FIG. 16B, instead of the electric charge accumulating layer 132, an electric charge accumulating layer 132b is disposed. In the electric charge accumulating layer 132b, a surface far from the conductive layer 110 has a width Z13b in the Z-direction and a surface close to the conductive layer 110 has a width in the Z-direction smaller than the width Z13b. In this case, the electric charge accumulating layer 132b is disposed such that the width Z13b is set to be equal to the width Z11 or smaller than the width Z11 by respective offset amounts Δb at an upper end and a lower end in the Z-direction.

In addition, the electric charge accumulating layer 132 may be disposed such that the width in the Z-direction has the maximum width at any position from the surface close to the conductive layer 110 to the surface far from the conductive layer 110. Also, in this case, the electric charge accumulating layer 132 is disposed such that the maximum width in the Z-direction is equal to the width Z11 of the surface S1 of the conductive layer 110 or smaller than the width Z11.

[Effect in Modification]

In any of the modifications illustrated in FIG. 16A and FIG. 16B, the electric charge accumulating layer 132a and the electric charge accumulating layer 132b are disposed such that the width Z13a and the width Z13b as the maximum width in the Z-direction of the electric charge accumulating layer 132a and the electric charge accumulating layer 132b are each almost equal to the width Z11 in the Z-direction of the surface S1 of the conductive layer 110 or the width Z13a and the width Z13b are smaller than the width Z11.

In the structures illustrated in FIG. 16A and FIG. 16B, as described above, although the effect to shield the electric field by the electric charge accumulating layer 132a and the electric charge accumulating layer 132b is slightly weaken due to reduction of the thickness of the electric charge accumulating layers 132a and 132b at both end portions in the Z-direction, the effective shield effect can still be exerted by presence of the electric charge accumulating layers 132a and 132b. Therefore, satisfactory read characteristics can be achieved.

### Second Embodiment

[Configuration]

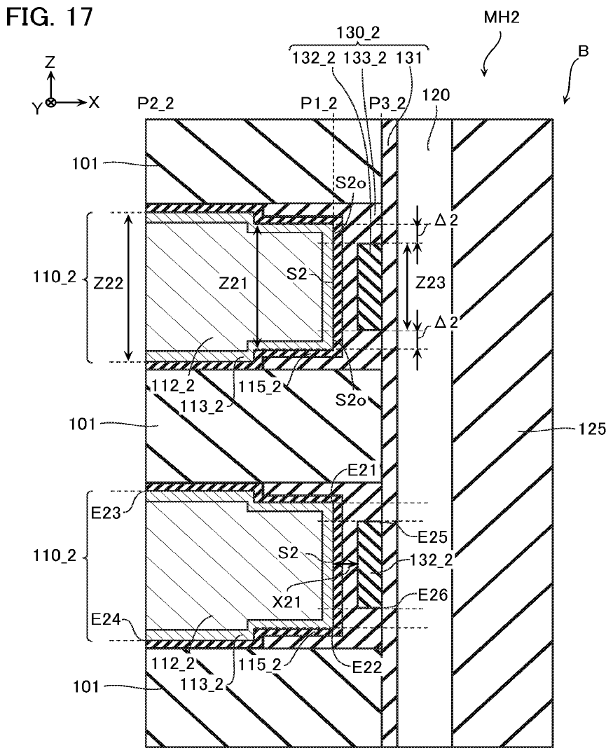

Next, with reference to FIG. 17, the configuration of the semiconductor memory device according to the second embodiment is described. FIG. 17 is a schematic cross-sectional view illustrating the exemplary configuration of the semiconductor memory device according to the second embodiment.

While FIG. 17 illustrates a configuration on a cross-sectional surface (XZ cross-sectional surface) along the X-direction and the Z-direction of a part of a memory hole structure MH2, the memory hole structure MH2 includes a similar configuration even on a cross-sectional surface along an extending direction of a conductive layer 1102 other than the X-direction and the Z-direction. In the following, while the configuration of the embodiment is continuously described with, for example, the X-direction taken as the extending direction of the conductive layer 1102, cross-sectional configurations in other directions along the extending direction of the conductive layer 1102 are also similarly understood.

[Structure of Memory Cell MC]

As illustrated in FIG. 17, the semiconductor memory device according to the embodiment is basically configured similarly to that of the semiconductor memory device according to the first embodiment. However, the semiconductor memory device according to the embodiment includes the conductive layer 110_2 instead of the conductive layer 110. The conductive layer 110_2 includes a conductive layer 112_2 and a barrier metal layer 113_2 that covers an upper surface, a lower surface, and a side surface of the conductive layer 112_2. The upper surface, the lower surface, and the side surface of the conductive layer 110_2 are covered by an insulating layer 115_2 made of the high dielectric constant film.

The semiconductor memory device according to the embodiment includes a gate insulating layer 130_2 instead of the gate insulating layer 130. The gate insulating layer 130_2 includes an electric charge accumulating layer 132_2, a block insulating layer 133_2, and the tunnel insulating layer 131. The width in the Z direction of the conductive layer 110_2 is disposed so as to decrease in stages as getting closer to the electric charge accumulating layer 132_2 side in the X-direction. That is, the conductive layer 110_2 is disposed such that the side opposed to the semiconductor layer 120 has a shape tapered in stages.

The conductive layer 110_2 has a width Z21 in the Z direction, at a first position P1_2 where a surface S2 opposed to the semiconductor layer 120 in the X-direction is disposed. The conductive layer 110_2 has a width Z22 in the Z direction, at a second position P2_2 apart from the electric charge accumulating layer 132 in the X-direction with respect to the first position P1_2. The width Z21 is smaller than the width Z22.

The surface S2 of the conductive layer 110_2 has no portion that approaches the semiconductor layer 120 when the surface is traced from the center to both ends in the Z direction. A distance between the surface S2 of the conductive layer 110_2 and the semiconductor layer 120 is substantially constant over an entire region in the Z direction, the entire region is where the surface S2 of the conductive layer 110_2 and the semiconductor layer 120 are mutually opposed and spaced in the X-direction. A separation distance X21 between an opposed surface where the electric charge accumulating layer 132_2 is opposed to the surface S2 of the conductive layer 110_2 and the surface S2 is substantially constant over an entire region in the Z direction. Note that the surface S2 may be disposed so as to be slightly separated from the semiconductor layer 120 between the center to both ends in the Z direction. The surface S2 may be a surface that is closest to and opposed to the semiconductor layer 120 in the X-direction. The opposed surface where the electric charge accumulating layer 132_2 is opposed to the surface S2 of the conductive layer 110_2 may be a surface where the electric charge accumulating layer 132_2 is closest to and opposed to the conductive layer 110_2.

The electric charge accumulating layer 132_2 has a width Z23 as the maximum width in the Z direction. The width Z23 is equal to the width Z21 of the surface S2 of the conductive layer 110_2 or smaller than the width Z21.

The surface S2 at the first position P1_2 of the conductive layer 110_2 has respective offset portions S2o on at least one side or both sides of the upper end portion and the lower end portion in the Z direction. An offset amount Δ2 as a length of the offset portion S2o in the Z direction is, for example, equal to or more than zero and smaller than (Z22-Z23)/2. Note that the offset amount Δ2 may be different from each another in the offset portions S2o on both sides in the Z direction.

The conductive layer 110_2 has a first end portion E21 on one side and a second end portion E22 on the other side in the Z direction. The first position P12 is where the surface S2 closest to and opposed to the semiconductor layer 120 in the X-direction is disposed. The conductive layer 110_2 has a third end portion E23 on one side and a fourth end portion E24 on the other side in the Z direction, at the second position P2_2. The second position P2_2 is farther from the electric charge accumulating layer 132_2 in the X-direction than the first position P12. The electric charge accumulating layer 132_2 has a fifth end portion E25 on one side and a sixth end portion E26 on the other side in the Z direction at a third position P3_2. The third position P3_2 is where the electric charge accumulating layer 132_2 has the maximum width in the Z direction. In the Z direction, the first end portion E21 may be positioned at a position same as the fifth end portion E25 or between the third end portion E23 and the fifth end portion E25. In the Z direction, the second end portion E22 may be positioned at a position same as the sixth end portion E26 or between the fourth end portion E24 and the sixth end portion E26.

The distance between the first end portion E21 and the fifth end portion E25 in the Z direction is equal to or more than zero and may be smaller than the distance between the third end portion E23 and the fifth end portion E25 in the Z direction. The distance between the second end portion E22 and the sixth end portion E26 in the Z direction is equal to or more than zero and may be smaller than the distance between the fourth end portion E24 and the sixth end portion E26 in the Z direction.

In a portion where the width in the Z direction of the conductive layer 110_2 is the width Z21, a part of the block insulating layer 133_2 is disposed so as to fill a space between the insulating layer 101 and the insulating layer 115_2. The block insulating layer 133_2 is disposed so as to continuously cover the upper and lower sides of the portion where the width in the Z direction of the conductive layer 110_2 is the width Z21 and the surface S2.

[Manufacturing Method]

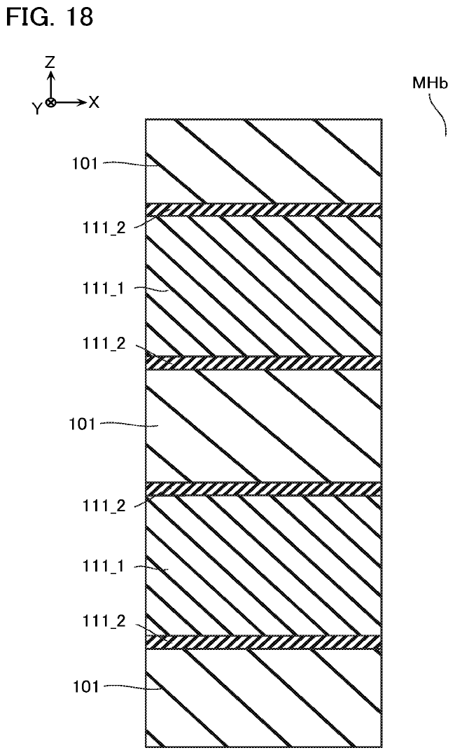

Next, with reference to FIG. 18 to FIG. 25, the manufacturing method of the semiconductor memory device according to the embodiment is described. FIG. 18 to FIG. 25 are partial cross-sectional views describing the manufacturing method of the semiconductor memory device illustrated in FIG. 17.

In the manufacturing method of the semiconductor memory device according to the embodiment, as illustrated in FIG. 5, the insulating layer 160, the conductive layer 152, and the semiconductor layer 151 are formed on the substrate 100. As illustrated in FIG. 18, a plurality of insulating layers 101, a plurality of first sacrifice layers 111_1, and a plurality of second sacrifice layers 111_2 are formed above these. At this time, the respective second sacrifice layers 111_2 are formed so as to be positioned between the layers of the insulating layer 101 and the first sacrifice layer 111_1.

The insulating layer 101 is made of, for example, silicon oxide (SiO₂) or the like. The first sacrifice layer 111_1 is made of, for example, silicon oxynitride (SiON) or the like. The second sacrifice layer 111_2 is made of, for example, silicon nitride (SiN) or the like. This process is performed, for example, by a method such as Chemical Vapor Deposition (CVD).

Next, as illustrated in FIG. 18, an opening MHb for forming the memory cell MC is formed in a stacked body made of the insulating layer 101, the first sacrifice layer 111_1, and the second sacrifice layer 111_2. This process is performed, for example, by a method such as Reactive Ion Etching (RIE).

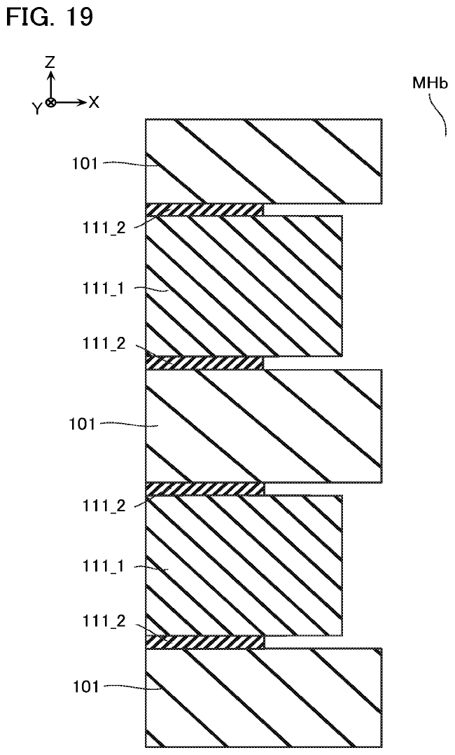

Next, as illustrated in FIG. 19, the etching that selectively recesses the first sacrifice layer 111_1 and the second sacrifice layer 111_2 of sidewalls facing the opening MHb in a stacked body made of the insulating layer 101, the first sacrifice layer 111_1, and the second sacrifice layer 111_2 backward with respect to the insulating layer 101 is performed. In this etching process, the second sacrifice layer 111_2 is formed as a layer where an etching rate is larger than the first sacrifice layer 111_1. Thus, the second sacrifice layer 111_2 is recessed backward more with respect to the insulating layer 101 than the first sacrifice layer 111_1. This process is performed, for example, by a method such as the wet etching or the dry etching.

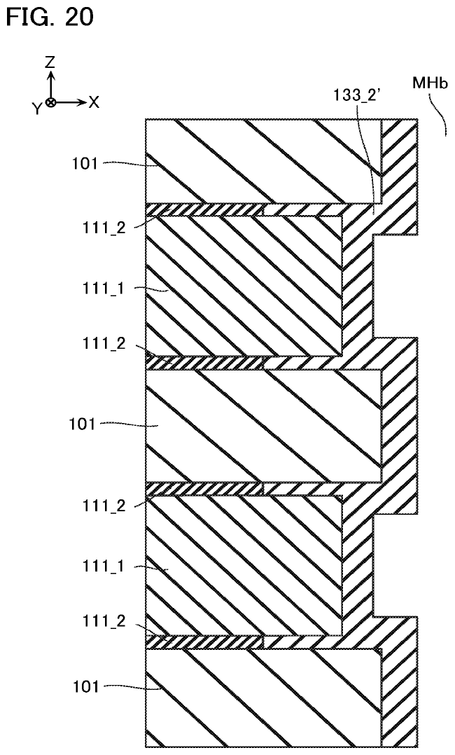

Next, as illustrated in FIG. 20, a block insulating layer 133_2′ is formed on a sidewall of the opening MHb with a thickness to an extent that does not fill a difference in level of the sidewall of the opening MHb. The block insulating layer 133_2′ also enters a cavity portion where the second sacrifice layer 111_2 has been recessed backward and formed to be formed. The block insulating layer 133 2′ is made of, for example, silicon oxide (SiO₂) or the like. This process is performed, for example, by a method such as CVD.

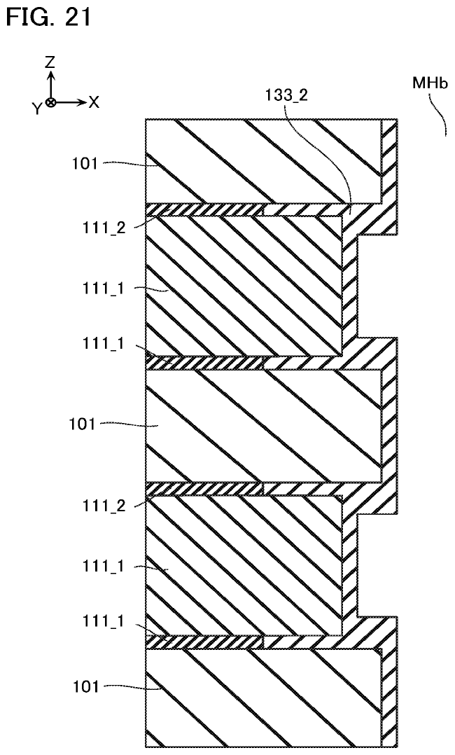

Next, as illustrated in FIG. 21, the recess etching that recesses the block insulating layer 133_2′ backward from the sidewall of the opening MHb to form the block insulating layer 133_2. With this process, the respective block insulating layers 133_2 formed on the sidewall portion of the insulating layer 101 and the sidewall portion of the first sacrifice layer 111_1 have suitable film thickness.

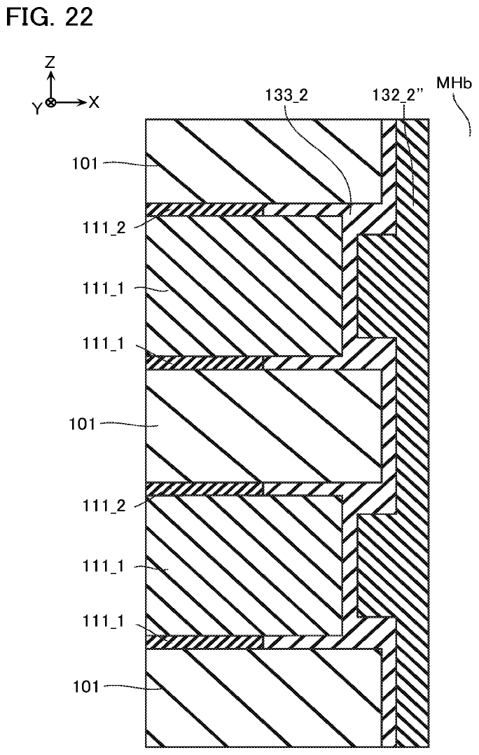

Subsequently, as illustrated in FIG. 22, an electric charge accumulating layer 132_2″ is formed on the block insulating layer 133_2 so as to fill the difference in level of the sidewall of the opening MHb. The electric charge accumulating layer 132_2″ maybe a film of, for example, silicon nitride (SiN) that can accumulate the electric charge or the like, or a floating gate made of polycrystalline silicon (Si) doped with N type impurities such as phosphorus (P) or P type impurities such as boron (B) or non-doped polycrystalline silicon (Si). This process is performed, for example, by a method such as CVD.

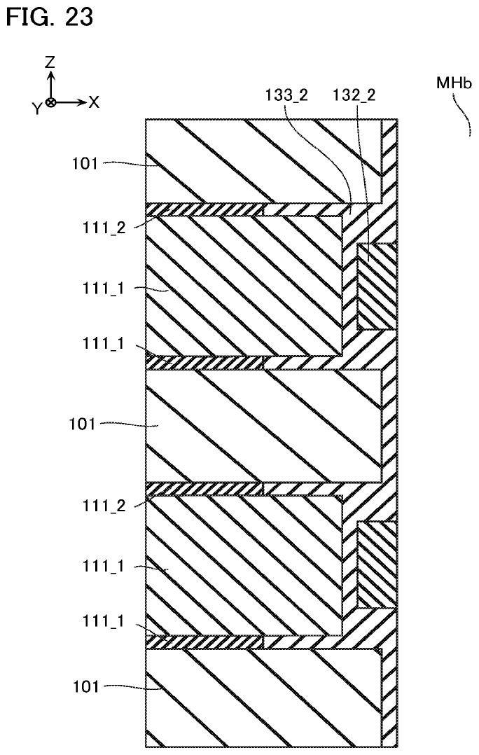

Next, as illustrated in FIG. 23, the recess etching that recess the electric charge accumulating layer 132_2″ backward is performed. This separates the electric charge accumulating layer 132_2″ in a stacking direction of the stacked body made of the insulating layer 101, the first sacrifice layer 111_1, and the second sacrifice layer 111_2, and only the electric charge accumulating layer 132_2 in the portion opposed to the center portion in the stacking direction of the first sacrifice layers 111_1 is left. This process is performed, for example, by a method such as the wet etching or the dry etching.

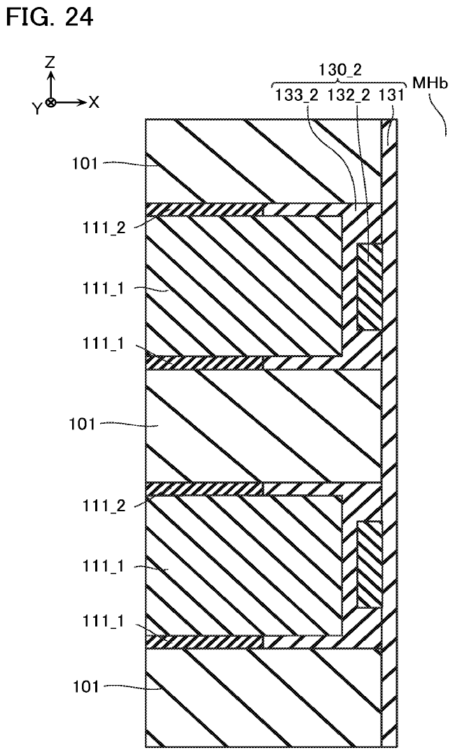

Next, as illustrated in FIG. 24, an exposed portion relative to the opening MHb is oxidized to form the tunnel insulating layer 131 on the inner wall of the opening MHb. The tunnel insulating layer 131 is made of, for example, silicon oxide (SiO₂) or the like. This process is performed, for example, by a method such as the thermal oxidation treatment where oxidant is used.

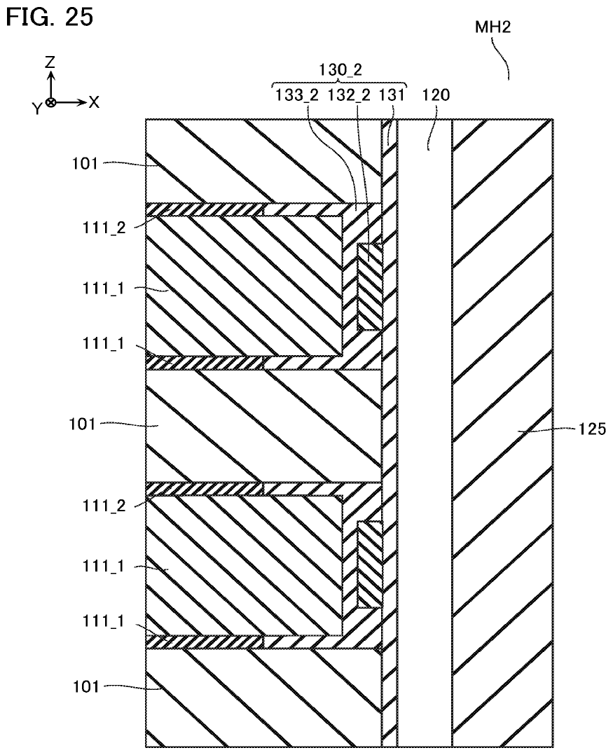

Next, as illustrated in FIG. 25, the semiconductor layer 120 and the insulating layer 125 are sequentially formed. Thus, the memory hole structure MH2 having a substantially columnar shape is formed. This process is performed, for example, by a method such as CVD. In this process, for example, the heat treatment for modifying the crystalline structure of the semiconductor layer 120, the formation processing of the semiconductor layer for the cap covering the upper end portion of the insulating layer 125 after recessing at least the upper end portion of the insulating layer 125 backward, and the like are performed.

Next, the plurality of first sacrifice layers 111_1 and second sacrifice layers 111_2 are removed via an opening (not illustrated) to form cavities. Subsequently, after the insulating layer 115_2 has been formed in the cavity formed by removing the first sacrifice layer 111_1 and the second sacrifice layer 111_2, the barrier metal layer 113_2 and the conductive layer 112_2 are sequentially formed to form the conductive layer 110_2. The process to remove the first sacrifice layer 111_1 and the second sacrifice layer 111_2 is performed, for example, by a method such as the wet etching.

The formation of the insulating layer 115_2, the barrier metal layer 113_2, and the conductive layer 112_2 is performed, for example, by a method such as CVD. With the processes described above, the configuration described with reference to FIG. 17 is formed.

[Effect]

In the structure of the second embodiment illustrated in FIG. 17A and FIG. 17B, by the electric charge accumulating layer 132_2, the shield effect can be achieved in the portions of the semiconductor layer 120 opposed to both end portions in the Z-direction of the conductive layer 110_2 and also the sufficient electric charge amount can be uniformly accumulated in the electric charge accumulating layer 132_2. Therefore, the reliability of the memory cell MC is improved.

[Other Embodiments]

In the embodiment, the memory layer ML that includes the memory hole structure MH (MH2) having the substantially cylindrical shape and the plurality of conductive layer 110 (110_2) covering the outer peripheral surface of the memory hole structure MH has been illustrated. However, the memory layer ML may have a structure where the memory hole structures MH having the substantially cylindrical shape are opposed to the different conductive layers 110 from both sides in the Y-direction. In this case, the semiconductor layer 120 and the gate insulating layer 130 may be separated or continuously formed in the Y-direction.

The memory layer ML may have a structure that includes a substantially plate-shaped memory trench structure MT extending in the X-direction and the Z-direction and the plurality of conductive layers 110 that are each positioned on both outsides of the memory trench structure MT and arranged in the Z-direction. The memory trench structure MT includes the plurality of semiconductor layers 120 extending in the Z-direction and the gate insulating layer 130 disposed between the respective semiconductor layers 120 and the plurality of conductive layers 110, on both side surfaces in the Y-direction inside the substantially plate-shaped trench structure.

[Others]

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of conductive layers arranged in a first direction;
a plurality of insulating layers each disposed between the plurality of conductive layers;
a semiconductor layer that extends in the first direction, the semiconductor layer being opposed to the plurality of conductive layers and the plurality of insulating layers in a second direction intersecting with the first direction; and
a plurality of electric charge accumulating layers opposed to the respective plurality of conductive layers and disposed between the plurality of conductive layers and the semiconductor layer, wherein
a conductive layer of the plurality of conductive layers has a first width in the first direction at a first position and has a second width in the first direction at a second position, the first position being where a surface opposed to the semiconductor layer in the second direction of the conductive layer is disposed, the second position being farther from an electric charge accumulating layer of the plurality of electric charge accumulating layers in the second direction than the first position,
the first width is smaller than the second width, and a third width as a maximum width in the first direction in the electric charge accumulating layer is equal to the first width or smaller than the first width, and
the surface opposed to the semiconductor layer at the first position of the conductive layer has no portion that approaches the electric charge accumulating layer when the surface is traced from a center of the surface to both ends of the surface in the first direction.

2. The semiconductor memory device according to claim 1, wherein
a separation distance in the second direction between the surface opposed to the semiconductor layer at the first position of the conductive layer and the semiconductor layer is substantially constant over the first direction.

3. The semiconductor memory device according to claim 1, wherein
a separation distance in the second direction between a surface opposed to the electric charge accumulating layer at the first position of the conductive layer and a surface closest to and opposed to the conductive layer of the electric charge accumulating layer is substantially constant over the first direction.

4. The semiconductor memory device according to claim 1, wherein
the conductive layer has an offset portion on at least one end portion of the conductive layer in the first direction at the first position, the offset portion is opposed to the semiconductor layer without via the electric charge accumulating layer, and an offset amount of the offset portion in the first direction with respect to the electric charge accumulating layer is smaller than a half of a value obtained by subtracting the third width from the second width.

5. The semiconductor memory device according to claim 1, wherein
the conductive layer has a first offset portion on one end portion and a second offset portion on the other end portion in the first direction at the first position, the first offset portion and the second offset portion are opposed to the semiconductor layer without via the electric charge accumulating layer, and offset amounts of the first offset portion and the second offset portion in the first direction with respect to the electric charge accumulating layer are each smaller than a half of a value obtained by subtracting the third width from the second width.

6. The semiconductor memory device according to claim 1, wherein
the conductive layer includes a portion where a width in the first direction monotonously increases, the portion separating away from the electric charge accumulating layer in the second direction farther than the first position.

7. The semiconductor memory device according to claim 1, wherein
the conductive layer includes:
a first part that has the first width being substantially constant over the second direction and extends in the second direction away from the electric charge accumulating layer with respect to the first position; and
a second part that has the second width being substantially constant over the second direction and extends in the second direction including the second position, and
the conductive layer has a difference in level in the first direction between the first part and the second part.

8. A semiconductor memory device comprising:
a plurality of conductive layers arranged in a first direction;
a plurality of insulating layers each disposed between the plurality of conductive layers;
a semiconductor layer that extends in the first direction, the semiconductor layer being opposed to the plurality of conductive layers and the plurality of insulating layers in a second direction intersecting with the first direction; and
a plurality of electric charge accumulating layers opposed to the respective plurality of conductive layers and disposed between the plurality of conductive layers and the semiconductor layer, wherein
a conductive layer of the plurality of conductive layers has a first width in the first direction at a first position and has a second width in the first direction ata second position, the first position being where a surface closest to and opposed to the semiconductor layer in the second direction of the conductive layer is disposed, the second position being farther from an electric charge accumulating layer of the plurality of electric charge accumulating layers than the first position in the second direction,
the first width is smaller than the second width, and a third width as a maximum width in the first direction in the electric charge accumulating layer is equal to the first width or smaller than the first width, and
the conductive layer has an offset portion on at least one end portion of the conductive layer in the first direction at the first position, the offset portion being opposed to the semiconductor layer without via the electric charge accumulating layer, or an offset amount in the first direction of the at least one end portion with respect to the electric charge accumulating layer is zero.

9. The semiconductor memory device according to claim 8, wherein
a separation distance in the second direction between the surface closest to and opposed to the semiconductor layer at the first position of the conductive layer and the semiconductor layer is substantially constant over the first direction.

10. The semiconductor memory device according to claim 8, wherein
a separation distance in the second direction between a surface closest to and opposed to the electric charge accumulating layer at the first position of the conductive layer and a surface closest to and opposed to the conductive layer of the electric charge accumulating layer is substantially constant over the first direction.

11. The semiconductor memory device according to claim 8, wherein
an offset amount of the offset portion in the first direction with respect to the electric charge accumulating layer is smaller than a half of a value obtained by subtracting the third width from the second width.

12. The semiconductor memory device according to claim 8, wherein
the conductive layer has a first offset portion on one end portion and a second offset portion on the other end portion in the first direction at the first position, the first offset portion and the second offset portion are opposed to the semiconductor layer without via the electric charge accumulating layer, and offset amounts of the first offset portion and the second offset portion in the first direction with respect to the electric charge accumulating layer are each smaller than a half of a value obtained by subtracting the third width from the second width.

13. The semiconductor memory device according to claim 8, wherein
the conductive layer includes a portion where a width in the first direction monotonously increases, the portion separating away from the electric charge accumulating layer in the second direction farther than the first position.

14. The semiconductor memory device according to claim 8, wherein
the conductive layer includes:
a first part that has the first width being substantially constant over the second direction and extends in the second direction away from the electric charge accumulating layer with respect to the first position; and
a second part that has the second width being substantially constant over the second direction and extends in the second direction including the second position, and
the conductive layer has a difference in level in the first direction between the first part and the second part.

15. A semiconductor memory device comprising:
a plurality of conductive layers arranged in a first direction;
a plurality of insulating layers each disposed between the plurality of conductive layers;
a semiconductor layer that extends in the first direction, the semiconductor layer being opposed to the plurality of conductive layers and the plurality of insulating layers in a second direction intersecting with the first direction; and
a plurality of electric charge accumulating layers opposed to the respective plurality of conductive layers and disposed between the plurality of conductive layers and the semiconductor layer, wherein
a conductive layer of the plurality of conductive layers has a first end portion on one side and a second end portion on the other side in the first direction at a first position and has a third end portion on one side and a fourth end portion on the other side in the first direction at a second position, the first position being where a surface closest to and opposed to the semiconductor layer in the second direction of the conductive layer is disposed, the second position being farther from an electric charge accumulating layer of the plurality of electric charge accumulating layers in the second direction than the first position,
the electric charge accumulating layer has a fifth end portion on one side and a sixth end portion on the other side in the first direction at a third position, the third position being where the electric charge accumulating layer has maximum width in the first direction,
the first end portion is positioned at a position same as the fifth end portion and different from the third end portion, or a position between the third end portion and the fifth end portion, in the first direction, and
the second end portion is positioned at a position same as the sixth end portion and different from the fourth end portion, or a position between the fourth end portion and the sixth end portion, in the first direction.

16. The semiconductor memory device according to claim 15, wherein
a separation distance in the second direction between the surface closest to and opposed to the semiconductor layer at the first position of the conductive layer and the semiconductor layer is substantially constant over the first direction.

17. The semiconductor memory device according to claim 15, wherein
a separation distance in the second direction between a surface closest to and opposed to the electric charge accumulating layer at the first position of the conductive layer and a surface closest to and opposed to the conductive layer of the electric charge accumulating layer is substantially constant over the first direction.

18. The semiconductor memory device according to claim 15, wherein
a distance between the first end portion and the fifth end portion in the first direction is equal to or more than zero and smaller than a distance between the third end portion and the fifth end portion in the first direction, and
a distance between the second end portion and the sixth end portion in the first direction is equal to or more than zero and smaller than a distance between the fourth end portion and the sixth end portion in the first direction.

19. The semiconductor memory device according to claim 15, wherein
the conductive layer includes a portion where a width in the first direction monotonously increases, the portion separating away from the electric charge accumulating layer in the second direction farther than the first position.

20. The semiconductor memory device according to claim 15, wherein
the conductive layer includes:
a first part that has a first width being substantially constant over the second direction and extends in the second direction away from the electric charge accumulating layer with respect to the first position; and
a second part that has a second width being substantially constant over the second direction and extends in the second direction including the second position, the first width being smaller than the second width, and
the conductive layer has a difference in level in the first direction between the first part and the second part.
